(19) United States
(12) Patent Application Publication
(10) Pub. No.: US 2024/0021333 A1
(43) Pub. Date: Jan. 18, 2024

(54) DEVICES, SYSTEMS, AND METHODS FOR ENHANCING THE IMPLEMENTATION OF CONTROL CIRCUITS FOR NUCLEAR INSTRUMENTATION AND CONTROL SYSTEMS

(71) Applicant: Westinghouse Electric Company LLC, Cranberry Township, PA (US)

(72) Inventors: Thomas TWEEDLE, Sewickley, PA (US); Paul A. BOBKO, Mars, PA (US)

(73) Assignee: Westinghouse Electric Company LLC, Cranberry Township, PA (US)

(21) Appl. No.: 17/813,295

(22) Filed: Jul. 18, 2022

(51) Int. Cl. G21D 3/00; G21D 3/04

(52) U.S. Cl. CPC G21D 3/008; G21D 3/04; G21D 3/001

(57) ABSTRACT

A nuclear instrumentation and control system is disclosed herein. The nuclear instrumentation and control system can include a housing and a plurality of selectively removable finished board assemblies configured to be installed within the hosing and electrically coupled to the instrumentation and control system nuclear reactor. At least one of the selectively removable finished board assemblies includes an input/output circuit. The nuclear instrumentation and control system can further include a daughter card including a control circuit, wherein the daughter card is configured to be selectively coupled to the at least one selectively removable base board of the plurality of selectively removable base boards via a mechanical connector and an electrical connector.

### FIELD

The present disclosure is generally related to nuclear power generation and, more particularly, is directed to an improved control circuit configurations for enhanced robustness and versatility when applied in an nuclear instrumentation and control system of a nuclear reactor.

### SUMMARY

The following summary is provided to facilitate an understanding of some of the innovative features unique to the aspects disclosed herein, and is not intended to be a full description. A full appreciation of the various aspects can be gained by taking the entire specification, claims, and abstract as a whole.

In various aspects, a nuclear instrumentation and control system is disclosed. The nuclear instrumentation and control system can include a housing and a plurality of selectively removable baseboards configured to be installed within the housing and electrically coupled to the instrumentation and control system nuclear reactor. At least one of the selectively removable baseboards includes an input/output circuit. The nuclear instrumentation and control system can further include a daughter board including a control circuit, wherein the daughter board is configured to be selectively coupled to the at least one selectively removable baseboard of the plurality of selectively removable baseboards via a mechanical connector and an electrical connector.

In various aspects, a plurality of selectively removable baseboards configured for use in a nuclear instrumentation and control system is disclosed. At least one of the selectively removable baseboards can include an input/output circuit and a daughter board including a control circuit, wherein the daughter board is configured to be selectively coupled to the at least one selectively removable baseboard of the plurality of selectively removable baseboards via a mechanical connector and an electrical connector.

In various aspects, a method of reducing a risk of common cause failure of a nuclear instrumentation and control system is disclosed. The method can include electrically coupling a first daughter board including a first control circuit to a first input/output circuit of a first selectively removable baseboard of the instrumentation and control system, installing the first selectively removable baseboard into the instrumentation and control system, electrically coupling a second daughter board including a second control circuit to a second input/output circuit of a second selectively removable baseboard of the instrumentation and control system, wherein the first control circuit is different than the second control circuit, installing the second selectively removable baseboard into the instrumentation and control system, and monitoring, via the instrumentation and control system, a physical parameter of a nuclear reactor plant process.

These and other objects, features, and characteristics of the present invention, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

### BRIEF DESCRIPTION OF THE DRAWINGS

Various features of the aspects described herein are set forth with particularity in the appended claims. The various aspects, however, both as to organization and methods of operation, together with advantages thereof, may be understood in accordance with the following description taken in conjunction with the accompanying drawings as follows:

FIG. 1A illustrates a front view of an instrumentation and control system configured for use with a nuclear reactor, in accordance with at least one non-limiting aspect of the present disclosure;

FIG. 1B illustrates a perspective view of the nuclear instrumentation and control system of FIG. 1A, in accordance with at least one non-limiting aspect of the present disclosure;

FIG. 2 illustrates a representative base board configured for use with the nuclear instrumentation and control system of FIGS. 1A and 1B, in accordance with at least one non-limiting aspect of the present disclosure;

FIG. 3 illustrates a block diagram of a top view of the base board of FIG. 2, in accordance with at least one non-limiting aspect of the present disclosure;

FIG. 4 illustrates a block diagram of a top view of a daughter card configured for use with the base board of FIG. 2, in accordance with at least one non-limiting aspect of the present disclosure; and

FIG. 5 illustrates a method of enhancing the implementation of a control circuit for use with a nuclear instrumentation and control system, in accordance with at least one non-limiting aspect of the present disclosure.

Corresponding reference characters indicate corresponding parts throughout the several views. The exemplifications set out herein illustrate various aspects of the invention, in one form, and such exemplifications are not to be construed as limiting the scope of the invention in any manner.

### DETAILED DESCRIPTION

Numerous specific details are set forth to provide a thorough understanding of the overall structure, function, manufacture, and use of the aspects as described in the disclosure and illustrated in the accompanying drawings. Well-known operations, components, and elements have not been described in detail so as not to obscure the aspects described in the specification. The reader will understand that the aspects described and illustrated herein are non-limiting examples, and thus it can be appreciated that the specific structural and functional details disclosed herein may be representative and illustrative. Variations and changes thereto may be made without departing from the scope of the claims. Furthermore, it is to be understood that such terms as “forward”, “rearward”, “left”, “right”, “upwardly”, “downwardly”, and the like are words of convenience and are not to be construed as limiting terms.

In the following description, like reference characters designate like or corresponding parts throughout the several views of the drawings. Also in the following description, it is to be understood that such terms as “forward”, “rearward”, “left”, “right”, “upwardly”, “downwardly”, and the like are words of convenience and are not to be construed as limiting terms.

As used in any aspect herein, the term “control circuit” may refer to, for example, hardwired circuitry, programmable circuitry (e.g., a computer processor including one or more individual instruction processing cores, processing unit, processor, microcontroller, microcontroller unit, controller, digital signal processor (“DSP”), programmable logic device (“PLD”), programmable logic array (“PLA”), or field programmable gate array (“FPGA”), state machine circuitry, firmware that stores instructions executed by programmable circuitry, and any combination thereof. The control circuit may, collectively or individually, be embodied as circuitry that forms part of a larger system, for example, an integrated circuit (“IC”), an application-specific integrated circuit (“ASIC”), a system on-chip (“SoC”), desktop computers, laptop computers, tablet computers, servers, smart phones, etc. Accordingly, as used herein “control circuit” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof. Additionally, it shall be appreciated that, as referenced herein, any specific type of control circuit can be effectively interchanged with any of the control circuits described above.

As used in any aspect herein, the term “logic” may refer to an app, software, firmware and/or circuitry configured to perform any of the aforementioned operations. Software may be embodied as a software package, code, instructions, instruction sets and/or data recorded on non-transitory computer readable storage medium. Firmware may be embodied as code, instructions or instruction sets and/or data that are hard-coded (e.g., non-volatile) in memory devices.

As used in any aspect herein, the terms “component,” “system,” “module” and the like can refer to a computer-related entity, either hardware, a combination of hardware and software, software, or software in execution.

As used in any aspect herein, an “algorithm” refers to a self-consistent sequence of steps leading to a desired result, where a “step” refers to a manipulation of physical quantities and/or logic states which may, though need not necessarily, take the form of electrical or magnetic signals capable of being stored, transferred, combined, compared, and otherwise manipulated. It is common usage to refer to these signals as bits, values, elements, symbols, characters, terms, numbers, or the like. These and similar terms may be associated with the appropriate physical quantities and are merely convenient labels applied to these quantities and/or states.

Before explaining various aspects of the articulated manipulator in detail, it should be noted that the illustrative examples are not limited in application or use to the details of construction and arrangement of parts illustrated in the accompanying drawings and description. The illustrative examples may be implemented or incorporated in other aspects, variations, and modifications, and may be practiced or carried out in various ways. Further, unless otherwise indicated, the terms and expressions employed herein have been chosen for the purpose of describing the illustrative examples for the convenience of the reader and are not for the purpose of limitation thereof. Also, it will be appreciated that one or more of the following-described aspects, expressions of aspects, and/or examples, can be combined with any one or more of the other following-described aspects, expressions of aspects, and/or examples.

As nuclear reactors become increasingly complex, nuclear control systems have also increased in complexity and can require a certain degree of customization provided via control circuits, such as specifically programmed processors and/or custom field programmable gate arrays (“FPGAs”). However, custom FPGAs can be expensive to design and manufacture. The difficulties and expenses associated with custom FPGA designs are only compounded due to the criticality of a nuclear control system's functionality. Obviously, failure of a nuclear instrumentation and control system for a nuclear reactor could produce catastrophic results. Accordingly, conventional FPGA designs have relied on human diversity in development, meaning, two separate design teams are necessary to produce a particular platform implementation. For example, two teams may be required to produce FPGAs for platform generic “slave” boards (e.g., input boards, output boards, communication boards, etc.), application specific integrated circuits (“ASIC”), and/or FPGAs. Although it can be expensive, redundant, and an inefficient use of resources, human diversity can successfully mitigate the risk of “common cause” failures and thus, enhance the reliability of the nuclear instrumentation and control system designed in this manner.

One non-limiting aspect of a nuclear instrumentation and control system for a nuclear reactor is the Advanced Logic System® (“ALS”) platform produced by Westinghouse Electric Company. For example, the ALS is a hardware-based architecture that incorporates self-test capability for detection and mitigation of the effects of failures within or external to the system. The ALS platform design utilizes a custom-built FPGA containing programmable logic components and programmable interconnects, which can be combined into more complex combinational functions such as decoders or math functions. In other words, the FPGA can be utilized to perform necessary functions of generic boards (e.g., slave boards) of the ALS, such as input/output (“I/O”) boards for plant processes and/or application specific boards (e.g., core logic board (“CLBs”) configured for the specific application of the ALS. Conventional nuclear instrumentation and control systems, such as the first version of the ALS, have included the bonding of FPGAs to baseboards, with I/O circuitry deployed on the same baseboard. This renders each board inflexible and, in the event of an FPGA failure, extremely expensive to replace. As such, conventional instrumentation and control systems for nuclear applications utilize the aforementioned (and inefficient) human diversity development processes to mitigate the risks of FPGA failure. Accordingly, there is a need for devices, systems, and methods for enhancing the implementation of control circuits for nuclear instrumentation and control systems.

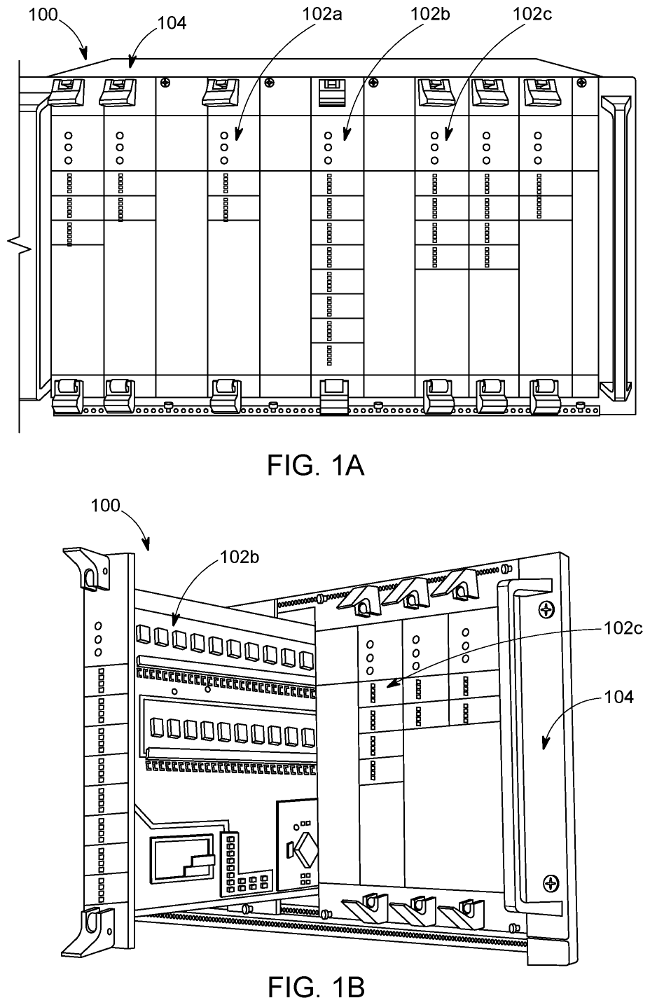

Referring now to FIG. 1A, a front view of an instrumentation and control system 100 configured for use with a nuclear reactor is depicted in accordance with at least one non-limiting aspect of the present disclosure. According to the non-limiting aspect of FIG. 1A, the instrumentation and control system 100 can include one or more boards 102_{a-c} configured to be inserted within and mechanically and electrically coupled to a housing 104. For example, the one or more boards 102_{a-c} can include a core logic board 102ₐ, an input/output board 102_{b}, and/or a communication board 102_{a-c}. For example, the core logic board 102ₐ can be configured to function via primary decision making circuitry, which can include the functional logic for the instrumentation and control system 100 with a data link interface to external systems.

The input/output board 102_{b} can be configured to convert specific types of field signals to digital signals and to perform a certain filtering of inputs, amongst other signal conveyance and processing functions. The communication board 102_{c} can provide a bidirectional datalink interface with other controllers, for example. Of course, it shall be appreciated that the core logic board 102ₐ, the input/output board 102_{b}, and the communication board 102_{c} of FIG. 1A are presented merely for illustrative purposes. Accordingly, any number and/or type of boards can be implemented via the instrumentation and control system 100 of FIG. 1 depending on user preference and/or intended application. Collectively, the boards 102_{a-c} can provide a universal, high-reliability, control system platform that enables diagnostics, testability, and modularity for the instrumentation and control system 100 of FIG. 1A, which targets safety-critical control capable of Class 1E certification from the U.S. Nuclear Regulatory Commission for use with systems such as, reactor protection system (“RPS”) and/or engineering safety feature actuation system (“ESFAS”) applications, for example. However, it shall be appreciated that the instrumentation and control system 100 of FIG. 1A can have any number of nuclear applications and shall not be limited to those described herein.

Referring now to FIG. 1B, a perspective view of the nuclear instrumentation and control system 100 of FIG. 1A is depicted in accordance with at least one non-limiting aspect of the present disclosure. Specifically, FIG. 1B illustrates how the slave boards 102_{a-c} can be selectively inserted into and, in the case of FIG. 1B, removed from the housing 104 of the instrumentation and control system 100. Accordingly, the instrumentation and control system 100 can be configured as a slave board 102_{a-c} based device, wherein each slave board 102_{a-c} can be selectively and mechanically coupled and to—and subsequently removed from—the housing 104. Once each slave board is mechanically coupled within the housing, requisite electrical connections (not shown) can be established such that the slave board 102_{a-c} is electrically coupled to a system interface (not shown) within the housing 104, which enables each slave board 102_{a-c} to work together to accomplish the programmed functions of the instrumentation and control system 100.

For example, the various slave boards 102_{a-c} can be configured such that the instrumentation and control system 100 of FIG. 1A functions as a reactor protection system (“RPS”), a reactor trip system (“RTS”), an engineering safety feature actuation system (“ESFAS”), an emergency load shed and diesel load sequencer (“DLS”), a main steam and feedwater isolation system (“MSFIS”), a thermocouple core cooling monitor (“TCCM”), a post-accident monitoring system (“PAMS”), and/or a safety-grade control system, amongst other nuclear-specific functions. It shall be appreciated that various boards 102_{a-c} of the instrumentation and control system 100 can be interchangeably swapped out to achieve the desired functionality depending on user preference and/or intended application. In other words, the instrumentation and control system 100 of FIGS. 1A and 1B can be modularly configured to provide input/output (I/O) and/or application-specific functionality in support of various plant processes.

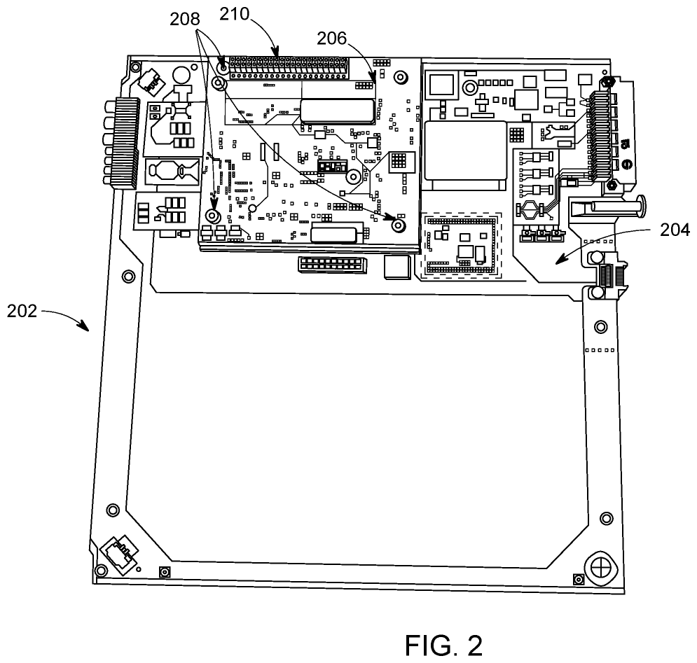

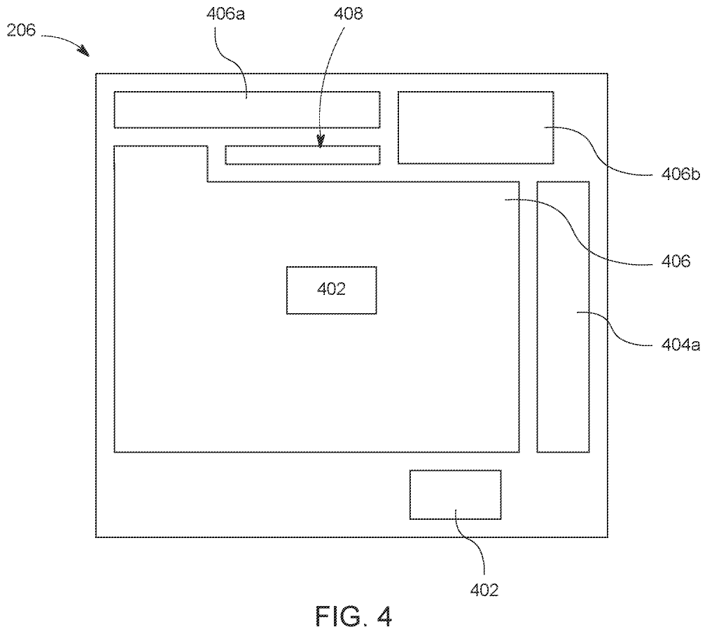

Referring now to FIG. 2, a representative slave board 202 configured for use with the nuclear instrumentation and control system 100 of FIGS. 1A and 1B is depicted in accordance with at least one non-limiting aspect of the present disclosure. According to the non-limiting aspect of FIG. 2, the slave board 202 can include a base board 204 and a daughter card 206 selectively and mechanically coupled to the base board 204. The daughter card 206 can include a circuit board—including any circuitry and components mounted to the daughter card 206—which can be safely decoupled from the base board 204 via one or more electrical connectors 210 and mechanical connectors 208. For example, the one or more electrical connectors can include a power and/or I/O connector or any other comparable port, including, but not limited to, an Integrated Drive Electronic (“IDE”) connector, a Small Computer Systems Interface (“SCSI”) connector, Peripheral Compoent Interconnect (“PCI”) connector, PCI Express (“PCIe”) connector, a universal serial bus (“USB”) connector, VITA 57.1 FMC (FPGA Mezzanine Card), Serial Peripheral Interface (“SPI”) connector, and/or a data bus (“DB”) connector, amongst others. According to some non-limiting aspects, the present disclosure contemplates electrical connectors 210 and mechanical connectors 208 with enhanced seismic robustness for application in a nuclear environment. For example, the electrical connectors 210 can include a larger number of pins (e.g., two-hundred to three-hundred, four-hundred, six-hundred pins) and/or the mechanical connectors 208 can include jack screws. In other words, the daughter card to base board electrical connection can be designed to be seismically robust. To ensure seismic withstand capability, the daughter card to base board electrical connections are designed to have a high decoupling force. Jack screws can be used for secure mechanical coupling of the daughter card to base board while proving the necessary decoupling force needed to separate the daughter card and base board without damaging either circuit board. Additionally, as will be described in further reference to FIG. 4, the daughter card 206 of FIG. 2 can include a control circuit and associated circuitry, which is conventionally positioned on the base board 204. Conversely, the base board 204 can include I/O circuitry, which is conventionally positioned on the daughter card 206.

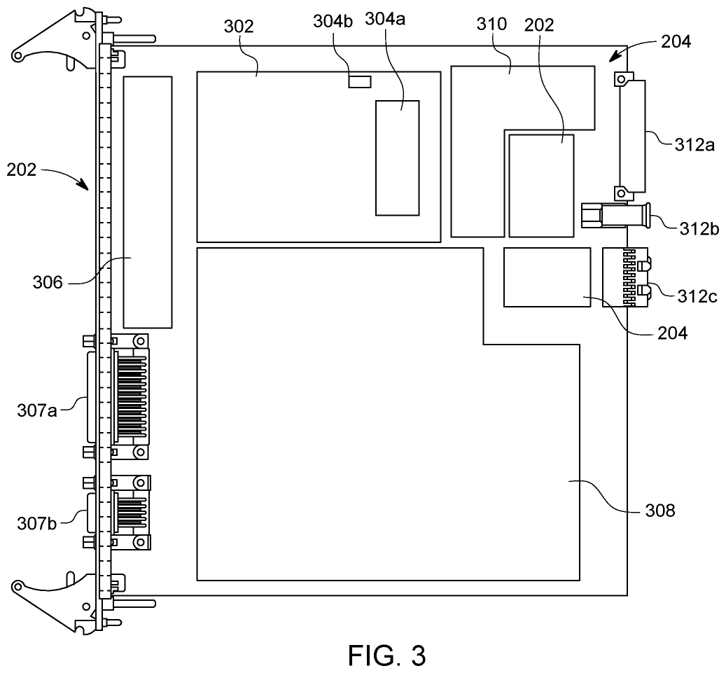

Referring now to FIG. 3, a block diagram of a top view of the base board 204 of the finished board assembly 202 of FIG. 2 is depicted in accordance with at least one non-limiting aspect of the present disclosure. According to the non-limiting aspect of FIG. 3, the base board 204 can include a footprint 302 for the daughter card 206 (FIGS. 2 and 4) with an electrical connectors 304ₐ, 304_{b} configured to establish electrical communication between the base board 204 and the daughter card 304. For example, the electrical connectors 304ₐ, 304_{b} can include any of the aforementioned power or I/O connectors, or any other connector configured to convey power and/or data to and from the daughter card 206 (FIGS. 2 and 4), when connected.

Still referring to FIG. 3, the base board 204 can further include a front panel interface 306, which can include one or more field connectors 307ₐ, 307_{b} and one or more lights (e.g., light emitting diodes, incandescent bulbs, etc.) indicating proper installation within the housing 104 (FIGS. 1A and 1B), one or more channel circuits 308, a power supply circuit 310, and/or one or more bus interface circuits 312_{a-c}. Of course, the circuits illustrated in FIG. 3 are merely illustrative and not intended to be limiting. Accordingly, it shall be appreciated that the baseboard 204 of FIG. 3 can be alternately configured to include any number of other circuits according to user preference and/or intended application.

Referring now to FIG. 4, a block diagram of a top view of a daughter card 206 configured for use with the finished board assembly 202 of FIG. 2 is depicted in accordance with at least one non-limiting aspect of the present disclosure. According to the non-limiting aspect of FIG. 4, the daughter card 206 can include a control circuit 402. For example, the control circuit 402 can include an FPGA. However, according to other non-limiting aspects, the control circuit 402 can include an ASIC, a processor, a microprocessor, or any other logic-based and/or instruction executing component, such as those disclosed herein.

In further reference of FIG. 4, the control circuit 402 can be mounted to logic and configuration circuitry 404 of the daughter card 206. The daughter card 206 can further include an electrical connector 404ₐ, 404_{b} that corresponds to the electrical connectors 304ₐ, 304_{b} of the base board 204, as depicted in FIG. 3. As previously mentioned the electrical connectors 404ₐ, 404_{b}, 304ₐ, 304_{b} (FIG. 3) can be specifically configured to convey power and/or I/O signals to and from the base board 204 (FIG. 3) and daughter board 206, when properly installed onto the base board 204. According to the non-limiting aspect of FIG. 3, the daughter card 206 can further include one or more power supplies 406ₐ, 406_{b} configured to deliver power to circuitry of the daughter card 206 and/or base board 204, as necessary.

Still referring to FIG. 4, the fact that the control circuit 402 is mounted to the daughter card 206 and not the base board 204 (FIGS. 2 and 3) provides the nuclear instrumentation and control system 100 (FIGS. 1A and 1B) with a certain degree of modular flexibility. In conventional nuclear instrumentation and control systems, the control circuit 402 and its associated circuitry would generally be mounted to the base board 204 with the relevant I/O circuitry mounted to a daughter card 206, if a daughter card is used. For example, control circuitry can include a highly integrated circuit that controls processing and/or data transfer functions. In other words, the control circuit 402, such as an FPGA, is permanently affixed to the baseboard and thus, can be extremely expensive and difficult to remove and replace. Accordingly, conventional nuclear instrumentation and control systems prioritize affordability and efficiency by including the control circuit on the base board, where it can interface with many different boards and sub-systems of the system. However, they achieve such benefits at the expense of a high risk of single-point failures. If the control circuit fails, the entire baseboard must be scrapped or, in a best case scenario, reworked. Obviously, this risk increases as the control circuit approaches obsolescence.

Contrarily, the daughter card 206 of FIG. 4 includes the control circuit 402 and thus, becomes a replaceable “personality” module for the functional logic circuitry on the base board 206 (FIG. 4). In this regard, the selective engagement of the daughter card 206 of FIG. 4 to the base board 204 of FIG. 3 via various mechanical connectors 208 (FIG. 2) and electrical connectors 210 (FIG. 2), 304ₐ, 304_{b} (FIG. 3), 404ₐ, 404_{b} can enhance the design, qualification, and test of new control circuits for the nuclear instrumentation and control system 100 (FIGS. 1A and 1B) by providing improved versatility, flexibility, and robustness. For example, if the control circuit 402 fails or requires replacement, the daughter card 206 can be easily repaired and/or replaced, without necessitating extensive rework on the baseboard 204 (FIGS. 2 and 3). In other words, the daughter card 206 and base board 204 (FIGS. 2 and 3) of the present disclosure enable robustness by eliminating the risks inherent to single-point control circuit failures. This promotes hardware diversity, which can reduce if not eliminate the aforementioned costs and inefficiencies associated with the human diversity approach to risk mitigation required by conventional designs. For example, the daughter card 206 design of FIG. 4 enables control circuits from different manufacturers to be utilized throughout the system 100 (FIG. 1), which creates a strong risk mitigating position than most human diversity approaches. Specifically, use of the daughter card 206 of FIG. 4 can reduce the independent verification and validation efforts necessary to certify two different control circuit designs for use in a nuclear system.

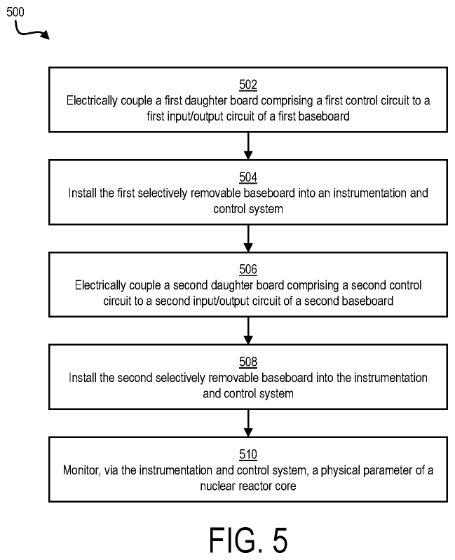

Referring now to FIG. 5, a method 500 of reducing a risk of common cause failure of a nuclear instrumentation and control system is depicted in accordance with at least one non-limiting aspect of the present disclosure. According to FIG. 5, the method 500 can include electrically coupling 502 a first daughter card comprising a first control circuit to a first selectively removable baseboard of the instrumentation and control system. The method 500 then calls for the installation 504 of the first selectively removable finished board assembly into the instrumentation and control system. A second daughter board comprising a second control circuit can likewise be electrically coupled 506 to a second selectively removable finished board assembly of the instrumentation and control system. Notably, the first control circuit can be different than the second control circuit, which can introduce hardware diversity in lieu of human diversity. Hardware diversity can adequately mitigate the risk of common cause failure when applied to a nuclear instrumentation and control system. The method 500 then calls for the installation 508 of the second selectively removable finished board assembly into the instrumentation and control system. Finally, a user can monitor 510, via the instrumentation and control system, a physical parameter (e.g., temperature, output, radiation level, etc.) of a nuclear reactor plant process.

Various aspects of the subject matter described herein are set out in the following numbered clauses:

Clause 1: A nuclear instrumentation and control system, including: a housing; a plurality of selectively removable finished board assemblies configured to be installed within the hosing and electrically coupled to the instrumentation and control system nuclear reactor, wherein at least one of the selectively removable finished board assemblies includes a base board with input/output circuit; and a daughter card including a control circuit, wherein the daughter card is configured to be selectively coupled to the at least one selectively removable base board of the plurality of selectively removable base boards via a mechanical connector and an electrical connector.

Clause 2: The nuclear instrumentation and control system according to clause 1, wherein the control circuit includes at least one of a field programmable gate array, an application specific integrated circuit, or a microprocessor.

Clause 3: The nuclear instrumentation and control system according to either clause 1 or 2, wherein the mechanical connector and the electrical connector are seismically robust.

Clause 4: The nuclear instrumentation and control system according to any of clauses 1-3, wherein the mechanical connector includes a jack screw.

Clause 5: The nuclear instrumentation and control system according to any of clauses 1-4, wherein the electrical connector includes greater than two-hundred pins but less than six-hundred pins.

Clause 6: The nuclear instrumentation and control system according to any of clauses 1-5, wherein the electrical connector includes four-hundred pins.

Clause 7: The nuclear instrumentation and control system according to any of clauses 1-6, wherein the daughter card further includes a core logic circuit.

Clause 8: The nuclear instrumentation and control system according to any of clauses 1-7, wherein the plurality of selectively removable finished board assemblies includes at least one of an input board, an output board, and a communication board, or combinations thereof.

Clause 9: The nuclear instrumentation and control system according to any of clauses 1-8, further including a second daughter card including a second control circuit, wherein the second daughter card is configured to be selectively coupled to the at least one selectively removable baseboard of the plurality of selectively removable finished board assemblies, and wherein the second control circuit is different than the control circuit.

Clause 10: The nuclear instrumentation and control system according to any of clauses 1-9, wherein the control circuit includes a different design than the second control circuit.

Clause 11: The nuclear instrumentation and control system according to any of clauses 1-10, wherein the control circuit includes a different manufacturer or product line than the second control circuit.

Clause 12: A plurality of selectively removable finished board assemblies configured for use in a nuclear instrumentation and control system, wherein at least one of the selectively removable finished board assemblies includes: a base board with input/output circuit; and a daughter card including a control circuit, wherein the daughter card is configured to be selectively coupled to the at least one selectively removable base board of the plurality of selectively removable base boards via a mechanical connector and an electrical connector.

Clause 13: The plurality of selectively removable base boards according to clauses 12, wherein the control circuit includes at least one of a field programmable gate array, an application specific integrated circuit, or a microprocessor.

Clause 14: The plurality of selectively removable base boards according to either of clauses 12 or 13, wherein the mechanical connector and the electrical connector are seismically robust.

Clause 15: The plurality of selectively removable base boards according to any of clauses 12-14, wherein the mechanical connector includes a jack screw.

Clause 16: The plurality of selectively removable base boards according to any of clauses 12-15, wherein the electrical connector includes four-hundred pins.

Clause 17: The plurality of selectively removable base boards according to any of clauses 12-16, wherein a second selectively removable base board of the plurality of selectively removable base boards includes a second daughter card including a second control circuit, wherein the second daughter card is configured to be selectively coupled to the second selectively removable baseboard of the plurality of selectively removable base boards, and wherein the second control circuit is different than the control circuit.

Clause 18: The plurality of selectively removable base boards according to any of clauses 12-17, wherein the control circuit includes a different design than the second control circuit.

Clause 19: The plurality of selectively removable base boards according to any of clauses 12-14, wherein the control circuit includes a different manufacturer or product line than the second control circuit.

Clause 20: A method of reducing a risk of common cause failure of a nuclear instrumentation and control system, the method including: electrically coupling a first daughter card including a first control circuit to a first input/output circuit of a first selectively removable base board of the instrumentation and control system; installing the first selectively removable finished board assembly into the instrumentation and control system; electrically coupling a second daughter card including a second control circuit to a second input/output circuit of a second selectively removable base board of the instrumentation and control system, wherein the first control circuit is different than the second control circuit; installing the second selectively removable finished board assembly into the instrumentation and control system; and monitoring, via the instrumentation and control system, a physical parameter of a nuclear reactor plant process.

All patents, patent applications, publications, or other disclosure material mentioned herein, are hereby incorporated by reference in their entirety as if each individual reference was expressly incorporated by reference respectively. All references, and any material, or portion thereof, that are said to be incorporated by reference herein are incorporated herein only to the extent that the incorporated material does not conflict with existing definitions, statements, or other disclosure material set forth in this disclosure. As such, and to the extent necessary, the disclosure as set forth herein supersedes any conflicting material incorporated herein by reference and the disclosure expressly set forth in the present application controls.

The present invention has been described with reference to various exemplary and illustrative aspects. The aspects described herein are understood as providing illustrative features of varying detail of various aspects of the disclosed invention; and therefore, unless otherwise specified, it is to be understood that, to the extent possible, one or more features, elements, components, constituents, ingredients, structures, modules, and/or aspects of the disclosed aspects may be combined, separated, interchanged, and/or rearranged with or relative to one or more other features, elements, components, constituents, ingredients, structures, modules, and/or aspects of the disclosed aspects without departing from the scope of the disclosed invention. Accordingly, it will be recognized by persons having ordinary skill in the art that various substitutions, modifications or combinations of any of the exemplary aspects may be made without departing from the scope of the invention. In addition, persons skilled in the art will recognize, or be able to ascertain using no more than routine experimentation, many equivalents to the various aspects of the invention described herein upon review of this specification. Thus, the invention is not limited by the description of the various aspects, but rather by the claims.

Those skilled in the art will recognize that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although claim recitations are presented in a sequence(s), it should be understood that the various operations may be performed in other orders than those which are described, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

It is worthy to note that any reference to “one aspect,” “an aspect,” “an exemplification,” “one exemplification,” and the like means that a particular feature, structure, or characteristic described in connection with the aspect is included in at least one aspect. Thus, appearances of the phrases “in one aspect,” “in an aspect,” “in an exemplification,” and “in one exemplification” in various places throughout the specification are not necessarily all referring to the same aspect. Furthermore, the particular features, structures or characteristics may be combined in any suitable manner in one or more aspects.

As used herein, the singular form of “a”, “an”, and “the” include the plural references unless the context clearly dictates otherwise.

Directional phrases used herein, such as, for example and without limitation, top, bottom, left, right, lower, upper, front, back, and variations thereof, shall relate to the orientation of the elements shown in the accompanying drawing and are not limiting upon the claims unless otherwise expressly stated.

The terms “about” or “approximately” as used in the present disclosure, unless otherwise specified, means an acceptable error for a particular value as determined by one of ordinary skill in the art, which depends in part on how the value is measured or determined. In certain aspects, the term “about” or “approximately” means within 1, 2, 3, or 4 standard deviations. In certain aspects, the term “about” or “approximately” means within 50%, 200%, 105%, 100%, 9%, 8%, 7%, 6%, 5%, 4%, 3%, 2%, 1%, 0.5%, or 0.05% of a given value or range.

In this specification, unless otherwise indicated, all numerical parameters are to be understood as being prefaced and modified in all instances by the term “about,” in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Any numerical range recited herein includes all sub-ranges subsumed within the recited range. For example, a range of “1 to 100” includes all sub-ranges between (and including) the recited minimum value of 1 and the recited maximum value of 100, that is, having a minimum value equal to or greater than 1 and a maximum value equal to or less than 100. Also, all ranges recited herein are inclusive of the end points of the recited ranges. For example, a range of “1 to 100” includes the end points 1 and 100. Any maximum numerical limitation recited in this specification is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited. All such ranges are inherently described in this specification.

Any patent application, patent, non-patent publication, or other disclosure material referred to in this specification and/or listed in any Application Data Sheet is incorporated by reference herein, to the extent that the incorporated materials is not inconsistent herewith. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system that “comprises,” “has,” “includes” or “contains” one or more elements possesses those one or more elements, but is not limited to possessing only those one or more elements. Likewise, an element of a system, device, or apparatus that “comprises,” “has,” “includes” or “contains” one or more features possesses those one or more features, but is not limited to possessing only those one or more features.

What is claimed is:

1. A nuclear instrumentation and control system, comprising:
a housing;
a plurality of selectively removable finished board assemblies configured to be installed within the hosing and electrically coupled to the instrumentation and control system nuclear plant process, wherein at least one of the selectively removable base boards comprises an input/output circuit; and
a daughter card comprising a control circuit, wherein the daughter card is configured to be selectively coupled to the at least one selectively removable base board of the plurality of selectively removable base boards via a mechanical connector and an electrical connector.

2. The nuclear instrumentation and control system of claim 1, wherein the control circuit comprises at least one of a field programmable gate array, an application specific integrated circuit, and a microprocessor.

3. The nuclear instrumentation and control system of claim 2, wherein the mechanical connector and the electrical connector are seismically robust.

4. The nuclear instrumentation and control system of claim 3, wherein the mechanical connector comprises a jack screw.

5. The nuclear instrumentation and control system of claim 3, wherein the electrical connector comprises greater than two-hundred pins but less than six-hundred pins.

6. The nuclear instrumentation and control system of claim 5, wherein the electrical connector comprises four-hundred pins.

7. The nuclear instrumentation and control system of claim 1, wherein the daughter board further comprises a functional logic circuit.

8. The nuclear instrumentation and control system of claim 1, wherein the plurality of selectively removable finished board assemblies comprises at least one of a core logic board, an input board, an output board, and a communication board, or combinations thereof.

9. The nuclear instrumentation and control system of claim 1, further comprising a second daughter card comprising a second control circuit, wherein the second daughter card is configured to be selectively coupled to the at least one selectively removable base board of the plurality of selectively removable base boards, and wherein the second control circuit is different than the control circuit.

10. The nuclear instrumentation and control system of claim 9, wherein the control circuit comprises a different design than the second control circuit.

11. The nuclear instrumentation and control system of claim 9, wherein the control circuit comprises a different manufacturer than the second control circuit.

12. A plurality of selectively removable base boards configured for use in a nuclear instrumentation and control system, wherein at least one of the selectively removable base boards comprises:
an input/output circuit; and
a daughter card comprising a control circuit, wherein the daughter card is configured to be selectively coupled to the at least one selectively removable base board of the plurality of selectively removable base boards via a mechanical connector and an electrical connector.

13. The plurality of selectively removable base boards of claim 12, wherein the control circuit comprises at least one of a field programmable gate array, an application specific integrated circuit, and a microprocessor.

14. The plurality of selectively removable base boards of claim 13, wherein the mechanical connector and the electrical connector are seismically robust.

15. The plurality of selectively removable base boards of claim 14, wherein the mechanical connector comprises a jack screw.

16. The plurality of selectively removable base boards of claim 14, wherein the electrical connector comprises four-hundred pins.

17. The plurality of selectively removable base boards of claim 12, wherein a second selectively removable base board of the plurality of selectively removable base boards comprises a second daughter card comprising a second control circuit, wherein the second daughter card is configured to be selectively coupled to the second selectively removable base board of the plurality of selectively removable base boards, and wherein the second control circuit is different than the control circuit.

18. The plurality of selectively removable baseboards of claim 17, wherein the control circuit comprises a different design than the second control circuit.

19. The plurality of selectively removable base boards of claim 17, wherein the control circuit comprises a different manufacturer than the second control circuit.

20. A method of reducing a risk of common cause failure of a nuclear instrumentation and control system, the method comprising:
electrically coupling a first daughter card comprising a first control circuit to a first input/output circuit of a first selectively removable base board of the instrumentation and control system;
installing the first selectively removable base board into the instrumentation and control system;
electrically coupling a second daughter card comprising a second control circuit to a second input/output circuit of a second selectively removable base board of the instrumentation and control system, wherein the first control circuit is different than the second control circuit;
installing the second selectively removable baseboard into the instrumentation and control system; and
monitoring, via the instrumentation and control system, a physical parameter of a nuclear reactor plant process.
